(19) United States
(12) Patent Application Publication
(10) Pub. No.: US 2025/0327179 A1
(43) Pub. Date: Oct. 23, 2025

(54) SYSTEMS, METHODS, AND STRUCTURES FOR THRESHOLD VOLTAGE CONTROL

(71) Applicant: ASM IP Holding B.V., Almere (NL)

(72) Inventors: Giuseppe Alessio Verni, Ismaning (DE); Rishabh Rastogi, Chandler, AZ (US); Jocelyn Kofi Brobbey, Phoenix, AZ (US); Suvidyakumar Vinod Homkar, Leuven (BE); Vivek Koladi Mootheri, Leuven (BE); Petro Deminskyi, Espoo (FI); Varun Sharma, Helsinki (FI); Ren-Jie Chang, Chandler, AZ (US); Yingqiu Zhou, Rugao/Nantong (CN); Patricio Eduardo Romero, Boutersem (BE); Charles Dezelah, Helsinki (FI); Michael Eugene Givens, Scottsdale, AZ (US); Vamsi Paruchuri, Mesa, AZ (US)

(21) Appl. No.: 19/184,898

(22) Filed: Apr. 21, 2025

Related U.S. Application Data
(60) Provisional application No. 63/637,061, filed on Apr. 22, 2024.

(51) Int. Cl. C23C 16/455; C23C 16/08; C23C 16/52; H10D 1/00

(52) U.S. Cl. CPC C23C 16/45527; C23C 16/08; C23C 16/45544; C23C 16/45553; C23C 16/52; H10D 1/047

(57) ABSTRACT

Semiconductor processing apparatuses and methods for forming dipoles, dipole-forming layers, and work function metals for use in integrated circuits. Related structures, such as metal-insulator-metal capacitors are described as well. Exemplary methods include contacting a substrate with a first precursor and a second precursor that comprise different elements.

### CROSS-REFERENCE TO RELATED APPLICATION(S)

This application claims the benefit of U.S. Provisional Application 63/637,061 filed on Apr. 22, 2024, the entire contents of which are incorporated herein by reference.

### FIELD

The present disclosure generally relates to methods and systems suitable for forming a layer on a surface of a substrate and to structures including the layer. More particularly, the disclosure relates to methods and systems for forming layers that allow controlling the threshold voltage of metal-oxide-semiconductor field-effect transistors (MOSFETs) and to structures formed using the methods and systems.

### BACKGROUND

Interface dipole engineering [IDE] is getting increasingly important for metal oxide field effect transistors (MOSFETs) as the channel dimensions are approaching below 5 nm. IDE improves the performance, modulating the effective work function (EWF) of metal gates, which can be employed to control the threshold voltage (Vt) of MOSFETs. Because of the different electronegativity of the various atoms in the interfacial layer, a dipole layer with an electric field can be formed altering the band alignment in the MOS stack. In order to improve energy efficiency and speed of integrated circuits, improved methods for threshold voltage control Vt are needed. There is furthermore a need for such methods that are compatible with current integration flows.

### BRIEF SUMMARY

Described herein is a semiconductor processing system comprising a reaction chamber, the reaction chamber comprising a substrate support that is constructed and arranged for supporting a substrate; a first precursor source comprising a first precursor comprising a first element; a second precursor source comprising a second precursor a second element, the second element being different from the first element; a gas distribution system comprising one or more reaction chamber valves, the gas distribution system being constructed and arranged for contacting the substrate with the first precursor and the second precursor; a sequence controller operably connected to the one or more reaction chamber valves and being programmed to cause the semiconductor processing system to execute a cyclical deposition process comprising one or more super cycles, wherein ones from the one or more super cycles comprise sequentially executing a first sub cycle and a second sub cycle; wherein the first sub cycle comprises a first precursor pulse that comprises operating the one or more reaction chamber valves to expose the substrate to the first precursor; wherein the second sub cycle comprises a second precursor pulse that comprises operating the one or more reaction chamber valves to expose the substrate to the second precursor; thereby forming a dipole-forming layer on the substrate, the dipole-forming layer comprising the first element and the second element.

In some embodiments, the first precursor further comprises one or more first ligands, wherein the second precursor further comprises one or more second ligands, and wherein the one or more first ligands are the same as the one or more second ligands.

In some embodiments, ones from the one or more first ligands and ones from the one or more first ligands are selected from the list consisting of acetate, amide, amidinate, cyclopentadienyl, and alkyl.

In some embodiments, the semiconductor processing system further comprises a first reactant source comprising a first reactant, wherein the first sub cycle further comprises a first reactant pulse that comprises operating the one or more reaction chamber valves to expose the substrate to the first reactant.

In some embodiments, the semiconductor processing system further comprises a second reactant source comprising a second reactant, wherein the second sub cycle further comprises a second reactant pulse that comprises operating the one or more reaction chamber valves to expose the substrate to the second reactant.

In some embodiments, the first reactant and the second reactant are the same.

In some embodiments, the first reactant and the second reactant are different.

In some embodiments, at least one of the first reactant and the second reactant is selected from a nitrogen reactant, an oxygen reactant, a boron reactant, a carbon reactant, a phosphorous reactant, a sulfur reactant, a selenium reactant, and a tellurium reactant.

In some embodiments, at least one of the first sub cycle and the second sub cycle comprises a halidation pulse, wherein the halidation pulse comprises exposing the substrate to a halogen reactant.

In some embodiments, at least one of the first element and the second element is selected from a transition metal, a post transition metal, and a rare earth metal.

In some embodiments, the first element is a p-type dipole shifter and wherein the second element is an n-type dipole shifter.

In some embodiments, the first element and the second element are p-type dipole shifters.

In some embodiments, the p-type dipole shifter is selected from aluminum and nickel.

In some embodiments, the first element and the second element are n-type dipole shifters.

In some embodiments, the n-type dipole shifter is selected from yttrium and lanthanum.

In some embodiments, at least one of the first element and the second element are selected from the list consisting of lanthanum (La), nickel (Ni), gallium (Ga), tantalum (Ta), magnesium (Mg), lutetium (Lu), hafnium (Hf), lanthanum (La), scandium (Sc), yttrium (Y), aluminum (Al), barium (Ba), strontium (Sr), titanium (Ti), vanadium (V), and gadolinium (Gd).

In some embodiments, the cyclical deposition process further comprises one or more etching steps, ones from the one or more etching steps comprising exposing the substrate to an etchant.

In some embodiments, the cyclical deposition process further comprises one or more etching cycles, ones from the one or more etching cycles comprising a conversion reactant pulse and a volatilization reactant pulse, wherein the conversion reactant comprises exposing the substrate to a conversion reactant, and wherein the volatilization reactant comprises exposing the substrate to a volatilization reactant.

In some embodiments, at least one of the first precursor and the second precursor comprises vanadium bis-mesitylene.

Further described herein is a method of forming a dipole-forming layer, comprising providing a substrate to a reaction chamber; executing a cyclical deposition process comprising one or more super cycles, wherein ones from the one or more super cycles comprise sequentially executing a first sub cycle and a second sub cycle; wherein the first sub cycle comprises a first precursor pulse that comprises exposing the substrate to a first precursor comprising a first element; wherein the second sub cycle comprises a second precursor pulse that comprises exposing the substrate to a second precursor comprising a second element; thereby forming a dipole-forming layer on the substrate, the dipole-forming layer comprising the first element and the second element.

Further described herein is a method of forming a layer comprising vanadium, wherein the method comprises providing a substrate to a reaction chamber and, executing a cyclical deposition process comprising a plurality of deposition cycles, ones from the plurality of deposition cycles comprising a precursor pulse and a reactant pulse, wherein the precursor pulse comprises exposing the substrate to a vanadium precursor, the vanadium precursor comprising vanadium and one or more aromatic ligands.

In some embodiments, the vanadium precursor comprises vanadium bis-mesitylene.

In some embodiments, the reactant comprises a nitrogen reactant.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a semiconductor processing system in accordance with one or more embodiments of the disclosure.

FIG. 2 to FIG. 5 illustrate cyclical deposition processes in accordance with one or more embodiments of the disclosure.

FIG. 6 illustrate a method of forming a layer comprising vanadium in accordance with one or more embodiments of the disclosure.

FIG. 7 illustrates a structure comprising a metal-insulator-semiconductor (MIS) capacitor in accordance with one or more embodiments of the disclosure.

FIG. 8 illustrates a method of forming a metal-insulator-semiconductor (MIS) capacitor in accordance with one or more embodiments of the disclosure.

FIG. 9 illustrates a further method of forming a metal-insulator-semiconductor (MIS) capacitor in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particularly disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g., subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes.”

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical de position processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, may include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally, or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g., using a noble gas, may be provided between a precursor pulse and a reactant pulse, thus avoiding, or at least minimizing gas phase interactions between the precursor and the reactant. It shall be understood that a purge can be affected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

The presently described systems, methods, and structures are useful for controlling the threshold voltage of field effect transistors. In particular, the present methods and devices are particularly useful for controlling the threshold voltage of n-channel or p-channel field effect transistors, such as n-channel- or p-channel metal-oxide semiconductor field effect transistors, such as n-channel or p-channel gate-all-around metal oxide semiconductor field effect transistors, for example complementary field effect transistors (CFETs). Advantageously, the presently disclosed methods allow depositing threshold shifting layers contributing only minimally to the equivalent oxide thickness of the gate dielectric stack. Advantageously, embodiments of the presently disclosed methods allow depositing threshold shifting layers having a low impurity content.

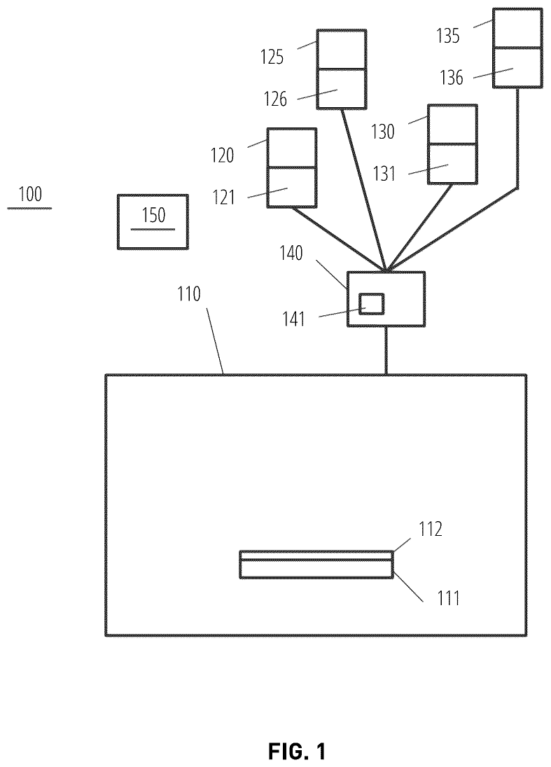

Referring to FIG. 1, described herein is an embodiment of a semiconductor processing system 100. The semiconductor processing system 100 comprises a reaction chamber 110. The reaction chamber 110 comprises a substrate support 111. The substrate support 111 is constructed and arranged for supporting a substrate 112. The semiconductor processing system 100 further comprises a first precursor source 120 that comprises a first precursor 121. The first precursor 121 comprises a first element. The semiconductor processing system 100 further comprises a second precursor source 130 that comprises a second precursor 131. The second precursor 131 comprises a second element. The second element and the first element are different. In other words, the second element and the first element are not the same. The semiconductor processing system 100 further comprises a gas distribution system 140. The gas distribution system 140 comprises one or more reaction chamber valves 141. The gas distribution system 140 is constructed and arranged for contacting the substrate with the first precursor 121 and the second precursor 131. The semiconductor processing system 100 further comprises a sequence controller 150. The sequence controller 150 is operably connected to the one or more reaction chamber valves. It is programmed to cause the semiconductor processing system to execute a cyclical deposition process.

Further described herein is a method of forming a dipole-forming layer. The method comprises providing a substrate to a reaction chamber. The method comprises executing a cyclical deposition process that comprises one or more super cycles. Ones from the one or more super cycles comprise sequentially executing a first sub cycle and a second sub cycle. The first sub cycle comprises a first precursor pulse that comprises exposing the substrate to a first precursor comprising a first element. The second sub cycle comprises a second precursor pulse that comprises exposing the substrate to a second precursor comprising a second element. Thus, a dipole-forming layer is formed on the substrate. The dipole-forming layer comprises the first element and the second element. Advantageously, dipole-forming layers according to embodiments of the present disclosure can be thermally stable and can have good etch resistance, e.g., towards capping layers.

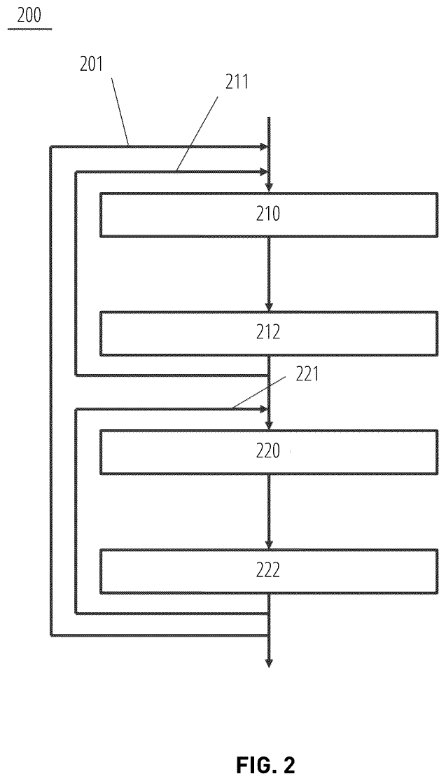

An embodiment of a cyclical deposition process 200 is described by reference to FIG. 2. The cyclical deposition process 200 comprises one or more super cycles 201. Ones from the one or more super cycles 201 comprise sequentially executing a first sub cycle 211 and a second sub cycle 221. The first sub cycle 211 and the second sub cycle 221 can be executed in any order. For example, the first sub cycle 211 can be executed before the second sub cycle 221. Alternatively, the second sub cycle 221 can be executed before the first sub cycle 211. The first sub cycle 211 comprises a first precursor pulse 210. The first precursor pulse 210 comprises operating the one or more reaction chamber valves 141 to expose the substrate 112 to the first precursor 121. The second sub cycle 221 comprises a second precursor pulse 220. The second precursor pulse 220 comprises operating the one or more reaction chamber valves 141 to expose the substrate 112 to the second precursor 131.

Thus, a layer, e.g., dipole-forming layer, may be formed on the substrate 112. The dipole-forming layer comprises the first element and the second element.

In some embodiments, a cyclical deposition process can comprise from at least 1 to at most 10 super cycles, for example 1, 2, 3, 4, 5, or more super cycles. In some embodiments, a super cycle can comprise from at least 1 to at most 10 first sub cycles and from at least 1 to at most 10 second sub cycles, for example 4 first sub cycles and 9 second sub cycles.

In some embodiments, a semiconductor processing system 100 as described herein further comprises a first reactant source 125 that comprises a first reactant 126. In some embodiments, the first sub cycle 211 further comprises a first reactant pulse 212. The first reactant pulse 212 comprises operating the one or more reaction chamber valves 141 to expose the substrate 112 to the first reactant 126. Optionally, subsequent first precursor pulses 210 and first reactant pulses 212 are separated by a purge.

In some embodiments, a semiconductor processing system 100 as described herein further comprises a second reactant source 135 that comprises a second reactant 136. In some embodiments, the second sub cycle 221 comprises a second reactant pulse 222 that comprises operating the one or more reaction chamber valves 141 to expose the substrate 112 to the second reactant 136. Optionally, subsequent second precursor pulses 220 and second reactant pulses 222 are separated by a purge.

In some embodiments, the first reactant and the second reactant are the same.

In some embodiments, the first reactant and the second reactant are different.

In some embodiments, at least one of the first reactant and the second reactant is selected from a nitrogen reactant, an oxygen reactant, a boron reactant, a carbon reactant, a phosphorous reactant, a sulfur reactant, a selenium reactant, and a tellurium reactant. Thus, dipole-forming layers can be formed that comprise an element selected from nitrogen, oxygen, boron, carbon, phosphorous, sulfur, selenium, and tellurium.

Suitable oxygen reactants include oxygen and can be selected from the list comprising O₂, O₃, H₂O, CO₂, N₂O, NO, NO₂, and NO₃. In some embodiments, the oxygen reactant comprises one or more of oxygen ions, oxygen radicals, and an oxygen plasma.

Suitable sulfur reactants include sulfur and can comprise H₂S and alkyl sulfides such as (CH₃)₂S. In some embodiments, the sulfur reactant comprises one or more of sulfur radicals, sulfur ions, and a sulfur plasma.

Suitable selenium reactants include selenium and can comprise H₂Se and alkyl selenides such as (CH₃)₂Se. In some embodiments, the selenium reactant comprises one or more of selenium ions, selenium radicals, and selenium plasma.

Suitable tellurium reactants include tellurium and can comprise H₂Te and alkyl tellurides such as (CH₃)₂Te. In some embodiments, the tellurium reactant comprises one or more of tellurium ions, tellurium radicals, and tellurium plasma.

Suitable nitrogen reactants can include N₂, NH₃, hydrazine, and alkylhydrazines such as 1,1-dimethylhydrazine. In some embodiments, the nitrogen reactant comprises one or more of nitrogen ions, nitrogen radicals, and nitrogen plasma.

Suitable phosphorous reactants can include phosphorous hydrides such as PH₃. In some embodiments, the phosphorous reactant comprises one or more of phosphorous ions, phosphorous radicals, and phosphorous plasma.

Suitable carbon reactants can include alkanes such as CH₃. In some embodiments, the carbon reactant comprises one or more of carbon ions, carbon radicals, and carbon plasma.

Suitable boron reactants can include boranes such as B₂H₆. In some embodiments, the boron reactant comprises one or more of boron ions, boron radicals, and boron plasma.

It shall be understood that terms such as oxygen plasma, nitrogen plasma, etc. can refer to a plasma that is generated with a plasma gas that comprises the element (oxygen, nitrogen, . . . ) in question. The plasma gas can comprise other elements as well, for example one or more of hydrogen and a noble gas such as He, Ne, Ar, Kr, and Xe.

In some embodiments, at least one of the first sub cycle and the second sub cycle comprises a halidation pulse. In some embodiments, the first sub cycle comprises the halidation pulse comprises exposing the substrate to a halogen reactant. Halidation pulses can be advantageously employed for tuning the composition of a dipole-forming layer as described herein.

Suitable halogen reactants can include halogen hydrides such as HF, HCl, HBr, and HI. Suitable halogen reactants can include elemental halogens such as F₂, Cl₂, Br₂, and I₂.

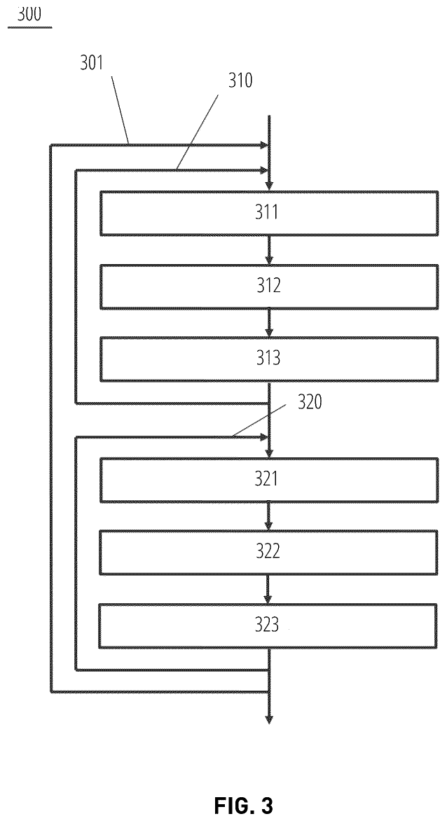

Referring to FIG. 3, an embodiment of a cyclical deposition process 300 that comprises halidation pulses 313,323 are described. In particular, the cyclical deposition process 300 comprises a plurality of super cycles 301. Ones from the plurality of super cycles 301 comprise one or more first sub cycles 310 and one or more second sub cycles 320. Ones from the one or more first sub cycles 310 comprise a first precursor pulse 311, a first reactant pulse 312, and a first halidation pulse 313. Ones from the one or more second sub cycles 320 comprise a second precursor pulse 321, a second reactant pulse 322, and a second halidation pulse 323.

For example, a dipole-forming layer may be formed as follows: after depositing lanthanum oxide, the substrate is contacted with a halogen reactant such that the lanthanum oxide surface is at least partially terminated with halogen. Then, the substrate is contacted with a scandium precursor to leach out lanthanum (e.g., as LaCl₃[tBu AMD], La-pivalate etc.), with tBu standing for tert-butyl and AMD for amidinate. Thus, the composition of a dipole-forming layer can be effectively controlled.

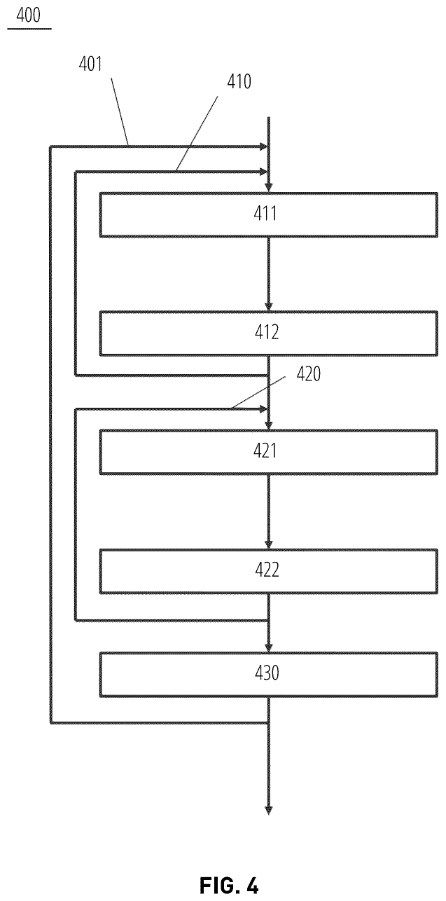

Referring to FIG. 4, in some embodiments, a cyclical deposition process 400 according to an embodiment of the present disclosure can comprise one or more etching steps 430. The cyclical deposition process 400 comprises a plurality of deposition cycles 401. Ones from the plurality of deposition cycles 401 comprise a first sub cycle 410 and a second sub cycle 420. The first sub cycle 410 comprises a first precursor pulse 411 and a second precursor pulse 412. The second sub cycle 420 comprises a second precursor pulse 421 and a second reactant pulse 422. As illustrated, ones from the plurality of deposition cycles 401 comprise an etching step 430 after the second sub cycle 420. Alternatively, the etching step can occur before the first sub cycle, between the first sub cycle and the second sub cycle, during the first sub cycle, and/or during the second sub cycle.

Thus, ones from the one or more etching steps can comprise exposing the substrate to an etchant. In such embodiments, a semiconductor processing system as described herein can suitably comprise an etchant source. Alternatively, the semiconductor processing system can be connected via an etchant line to an off-board etchant source.

In some embodiments, a cyclical deposition process as described herein further comprises one or more etching cycles. Ones from the one or more etching cycles comprise a conversion reactant pulse and a volatilization reactant pulse. The conversion reactant pulse comprises exposing the substrate to a conversion reactant. The volatilization reactant pulse comprises exposing the substrate to a volatilization reactant. Such a cyclical deposition process can be executed in an embodiment of a semiconductor processing apparatus as described herein. The semiconductor deposition apparatus can comprise one or more conversion reactant sources comprising a conversion reactant. Additionally, or alternatively, the semiconductor deposition apparatus can comprise one or more conversion reactant lines that are operationally connectable to an off-board conversion reactant source. The semiconductor deposition apparatus can comprise one or more volatilization reactant sources comprising a volatilization reactant. Additionally, or alternatively, the semiconductor deposition apparatus can comprise one or more volatilization reactant lines that are operationally connectable to an off-board volatilization reactant source.

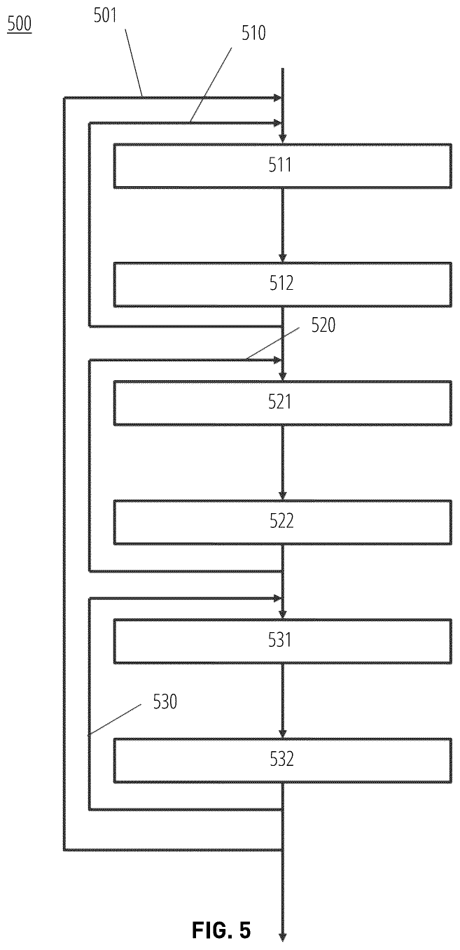

Referring to FIG. 5, in some embodiments, a cyclical deposition process 500 according to an embodiment of the present disclosure can comprise one or more etching cycles 530. In particular, the cyclical deposition process 500 comprises a plurality of deposition cycles 501. Ones from the plurality of deposition cycles 501 comprise one or more first sub cycles 510, one or more second sub cycles 520, and the one or more etching cycles 530. Ones from the one or more first sub cycles 510 comprises a first precursor pulse 511 and a second precursor pulse 512.

Ones from the one or more second sub cycles 520 comprises a second precursor pulse 521 and a second reactant pulse 522. Ones from the one or more etching cycles 530 comprise a conversion reactant pulse 531 and a volatilization reactant pulse 532. As illustrated, ones from the plurality of deposition cycles 501 comprise an etching cycle 530 after the second sub cycle 520. Alternatively, the etching step can occur before the one or more first sub cycles 510, between the one or more first sub cycles 510 and the one or more second sub cycles 520, after the one or more second sub cycles 520, during a first sub cycle 510, and/or during a second sub cycle 520.

For example, a conversion reactant can comprise one or more of a halogen reactant, an oxygen reactant, a sulfur reactant, a selenium reactant, a tellurium reactant, a phosphorous reactant, a nitrogen reactant, a carbon reactant, and a boron reactant as described herein.

For example, a volatilization reactant can comprise one or more of a halogen reactant, an oxygen reactant, a sulfur reactant, a selenium reactant, a tellurium reactant, a phosphorous reactant, a nitrogen reactant, a carbon reactant, and a boron reactant as described herein.

In some embodiments, the first and second precursors have the same ligands. In other words, in some embodiments, the first precursor further comprises one or more first ligands, the second precursor further comprises one or more second ligands, and the one or more first ligands are the same as the one or more second ligands.

In some embodiments, at least one of the first precursor and the second precursor comprises a transition metal precursor. In some embodiments, at least one of the first precursor and the second precursor comprises a transition metal precursor that comprises one or more aromatic ligands. For example, the one or more aromatic ligands can be selected from benzene and an alkyl-substituted benzene. For example, the transition metal precursor can comprise one or more ligands selected from the list consisting of methyl-substituted aromatic rings, ethyl-substituted aromatic rings, propyl-substituted aromatic rings, and butyl-substituted aromatic rings. For example, the one or more ligands can comprise 1, 2, 3, 4, 5, or 6 alkyl substituents. In some embodiments, the transition metal comprises vanadium. In some embodiments, at least one of the first precursor and the second precursor comprises vanadium bis-mesitylene.

In some embodiments, one of the first precursor and the second precursor can be represented by the following structure:

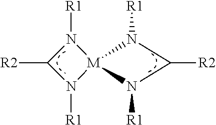

wherein M is a metal, R1 and R2 are independently selected from a C1 to C6 alkyl, alkenyl, and alkynyl. In some embodiments, R1 and R2 are independently selected from a C1 to C6 alkyl. In some embodiments, R2 is methyl, ethyl, or propyl. In some embodiments, R1 is propyl, butyl, or hexyl. In some embodiments, R1 is isopropyl and R2 is methyl. In some embodiments, M is an element as disclosed herein. In some embodiments, M is a transition metal such as nickel, vanadium, and titanium. In some embodiments, M is a rare earth metal such as lanthanum, ytterbium, yttrium, and scandium.

In some embodiments, one of the first precursor and the second precursor can be represented by MCp(allyl), wherein M is a metal, and Cp stands for cyclopentadienyl. In some embodiments, M is an element as disclosed herein. In some embodiments, M is a transition metal such as nickel, vanadium, and titanium. In some embodiments, M is a rare earth metal such as lanthanum, ytterbium, yttrium, and scandium.

In some embodiments, one of the first precursor and the second precursor can be represented by the formula Bis(alkylcyclopentadienyl) (N,N′-Dialkyllacetaminidinato) Metal (III). In some embodiments, alkylcyclopentadienyl can be selected from the list consisting of methylcyclopentadienyl, ethylcyclopentadienyl, and propylcyclopentadienyl. In some embodiments, N,N′-Dialkyllacetaminidinato can be selected from (N,N′-Dimethyllacetaminidinato), (N,N′-Diethylacetaminidinato), (N,N′-Dipropylacetaminidinato), (N,N′-Dibutylacetaminidinato), and (N,N′-Dipentylacetaminidinato). In some embodiments, the metal can be selected from a transition metal, a rare earth metal, and a post transition metal. In some embodiments, one of the first precursor and the second precursor can comprise bis(ethylcyclopentadienyl)(N,N′-Diisopropylacetaminidinato) Yttrium (III).

In some embodiments, one of the first precursor and the second precursor can be selected from the list consisting of bis(N,N′-di-t-butylacetamidinato)nickel(II), bis(1,4-di-tert-butyl-1,3-diazadienyl)nickel, bis(2,2,6,6-tetramethylheptane-3,5-dionato)nickel(II), Ni(Cp)₂, and Ni(RₙCp)₂, with R being a C1 to C6 alkyl and n being an integer from at least 1 to at most 3. For example, R can be methyl, ethyl, or propyl, and n can be 0, 1, 2, or 3. Cp stands for cyclopentadienyl.

In some embodiments, one of the first precursor and the second precursor can be selected from the list consisting of scandium tris (N,N′-diisopropylacetamidinate), Sc(RCp)₃, Sc(Cp)₃, with Cp standing for cyclopentadienyl and R for a C1-C6 alkyl, such as methyl, ethyl, propyl, and butyl. In some embodiments, one of the first precursor and the second precursor can comprise Sc(iPrCp)₃, with iPrCp standing for isopropyl-substituted cyclopentadienyl.

In some embodiments, ones from the one or more first ligands and ones from the one or more first ligands are selected from the list consisting of acetate, amide, amidinate, cyclopentadienyl, and alkyl.

In some embodiments, at least one of the first element and the second element is selected from a transition metal, a post transition metal, and a rare earth metal.

In some embodiments, the first element is a p-type dipole shifter, and the second element is an n-type dipole shifter. Thus two opposing dipole-forming layers can be formed. By combining two opposing dipole-forming layers in one stack, the benefits can be twofold: The opposing dipole-forming layer can be used to finely tune the shift if the minimum shift per unit area is too large to begin with. Additionally or alternatively, the opposing dipole-forming layer can be used as a potential capping layer to protect the main dipole-forming layer from any subsequent integration steps. Thus, the effective work function of gates/MIS structures can be controlled with precise steps (meV˜20 meV). This can advantageously allow integrating them together in multi-Vt devices.

For example, a dipole-forming layer as described herein can comprise a p-shifter such as NiO and an n-shifter such as Y₂O₃.

It shall be understood that an n-type dipole shifter can corresponds to a layer that decreases the threshold voltage of NMOS transistors: it may attract electrons to a semiconductor-dielectric interface. It shall be understood that a p-type dipole shifter corresponds to a layer that decreases the threshold voltage of PMOS transistors: it may attract holes to the semiconductor-dielectric interface.

In some embodiments, the first element and the second element are p-type dipole shifters.

In some embodiments, the first element and the second element are n-type dipole shifters.

In some embodiments, the n-type dipole shifter is selected from yttrium and lanthanum. For example, exemplary dipole-forming layers can include Y₂O₃ and La₂O₃.

In some embodiments, the p-type dipole shifter is selected from Al and Ni. For example, exemplary dipole-forming layers can include Al₂O₃ and NiO₂.

In some embodiments, at least one of the first element and the second element are selected from the list consisting of lanthanum (La), tantalum (Ta), strontium (Sr), titanium (Ti), vanadium (V), and gadolinium (Gd).

In some embodiments, the first element comprises nickel and the second element comprises yttrium.

In a particular embodiment, a dipole-forming layer was formed using a super cycle process, in particular an atomic layer deposition process, comprising a single super cycle that comprised five first sub cycles and six second sub cycles. The first element comprised nickel. The second element comprised yttrium. Both the first reactant and the second reactant were an oxygen reactant. When incorporated in a titanium nitride/hafnium oxide/p-silicon capacitor, it yielded an effective work function of 4.621 eV, and an equivalent oxide thickness of 1.67 nm.

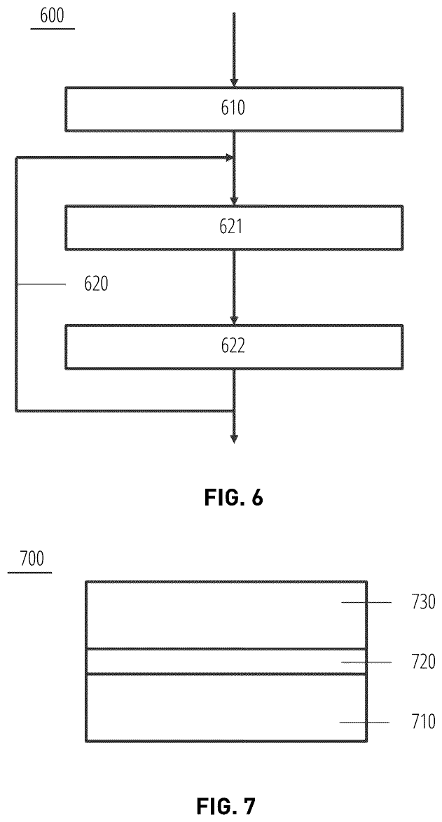

Referring to FIG. 6, further described herein is an embodiment of a method 600 of forming a layer comprising vanadium. The method 600 comprises providing 610 a substrate to a reaction chamber. The method 600 further comprises executing a cyclical deposition process. The cyclical deposition process comprises a plurality of deposition cycles 620. Ones from the plurality of deposition cycles 620 comprise a precursor pulse 621 and a reactant pulse 622. The precursor pulse 621 comprises exposing the substrate to a vanadium precursor. The vanadium precursor comprises vanadium and one or more aromatic ligands. The reactant pulse 622 can comprise exposing the substrate to a reactant. Suitable reactants include oxygen reactants, nitrogen reactants, boron reactants, carbon reactants, sulfur reactants, selenium reactants, and tellurium reactants as described herein. In some embodiments, the reactant comprises a nitrogen reactant such as ammonia. Thus, a vanadium nitride layer can be formed. Vanadium nitride can be employed as part of a dipole-forming layer as described herein. Additionally or alternatively, vanadium nitride can be employed as a work function metal layer of a metal gate for a MOSFET. In some embodiments, a vanadium-containing layer formed using a method as described herein can contain vanadium in one or more oxidation states, for example in one or more oxidation states selected from 0, +2, +3, +4, and +5.

In some embodiments, the vanadium precursor comprises vanadium bis-mesitylene. Vanadium nitride made using a cyclical deposition process, in particular atomic layer deposition (ALD), with a vanadium bis-mesitylene precursor and ammonia reactant were confirmed to result in a vanadium nitride film by means of X-ray photoelectron spectroscopy (XPS). Carbon impurities are absent despite the presence of carbon in the precursor, and despite a low substrate temperature during deposition of 250-300° C. An exemplary layer had a thickness of around 6 nm and a sheet resistance of around 400 Ohm/square.

FIG. 7 illustrates a structure 700 comprising a metal-insulator-semiconductor (MIS) capacitor. It comprises a semiconductor 710 such as silicon, an insulator 720 such as hafnium oxide comprising a dipole, and a gate 730 that can comprise a metal such as copper, cobalt, tungsten, ruthenium, molybdenum, titanium, vanadium, and the like. Embodiment of the present disclosure, e.g., dipoles, dipole-forming layers, and work function metals, can be employed to modulate the threshold voltage of transistors that comprise such a MIS capacitor.

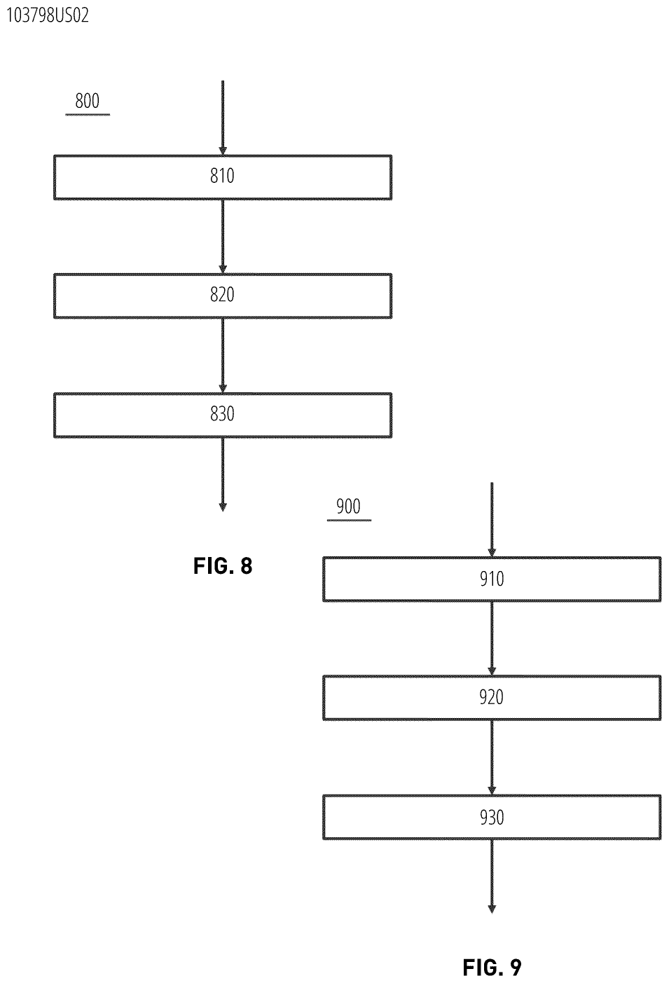

FIG. 8 illustrates an embodiment of a method 800 of forming a metal-insulator-semiconductor (MIS) capacitor. The method 800 comprises forming a dipole-forming layer 810 on a substrate, then forming a high-k dielectric 820 on the substrate, and then forming a metal layer 830 on the substrate. In such a dipole-first approach, a dipole-forming layer is deposited before the high-k dielectric. Dipole-forming layers are described elsewhere herein. Suitable high-k dielectrics include hafnium oxide, aluminum oxide, and zirconium oxide. Suitable metal layers include copper, cobalt, ruthenium, tungsten, and molybdenum.

FIG. 9 illustrates another embodiment of a method 900 of forming a metal-insulator-semiconductor (MIS) capacitor. The method 900 comprises forming a high-k dielectric 910 on a substrate, then forming a dipole layer 920 on the substrate, and then forming a metal layer 930 on the substrate. In such a dipole-last approach, a dipole-forming layer is deposited after the high-k dielectric.

Of course, in other approaches (not illustrated) a dipole layer can be deposited between two high-k layer deposition steps, or even during a high-k layer deposition step.

Regardless of whether the dipole-forming layer is deposited before the high-k dielectric (dipole first), after the high-k dielectric (dipole last), during a high-k dielectric deposition, or between two high-k deposition steps (dipole mid), the dipole-forming layer can form a dipole when it is subjected to an anneal, such as an anneal in nitrogen, in a noble gas such as argon, or in forming gas. The anneal can be carried out as a stand-alone step or together with a further processing step, e.g. together with metal layer formation.

1. A semiconductor processing system comprising:
a reaction chamber, the reaction chamber comprising a substrate support that is constructed and arranged for supporting a substrate;
a first precursor source comprising a first precursor comprising a first element;
a second precursor source comprising a second precursor a second element, the second element being different from the first element;
a gas distribution system comprising one or more reaction chamber valves, the gas distribution system being constructed and arranged for contacting the substrate with the first precursor and the second precursor; and
a sequence controller operably connected to the one or more reaction chamber valves and being programmed to cause the semiconductor processing system to execute a cyclical deposition process comprising one or more super cycles, wherein ones from the one or more super cycles comprise sequentially executing a first sub cycle and a second sub cycle,
wherein the first sub cycle comprises a first precursor pulse that comprises operating the one or more reaction chamber valves to expose the substrate to the first precursor,
wherein the second sub cycle comprises a second precursor pulse that comprises operating the one or more reaction chamber valves to expose the substrate to the second precursor,
to form a dipole-forming layer on the substrate, the dipole-forming layer comprising the first element and the second element.

2. The semiconductor processing system according to claim 1, wherein the first precursor further comprises one or more first ligands, wherein the second precursor further comprises one or more second ligands, and wherein the one or more first ligands are the same as the one or more second ligands.

3. The semiconductor processing system according to claim 2, wherein ones from the one or more first ligands and ones from the one or more first ligands are selected from a list consisting of acetate, amide, amidinate, cyclopentadienyl, and alkyl.

4. The semiconductor processing system according to claim 1 further comprising a first reactant source comprising a first reactant, wherein the first sub cycle further comprises a first reactant pulse that comprises operating the one or more reaction chamber valves to expose the substrate to the first reactant.

5. The semiconductor processing system according to claim 4 further comprising a second reactant source comprising a second reactant, wherein the second sub cycle further comprises a second reactant pulse that comprises operating the one or more reaction chamber valves to expose the substrate to the second reactant.

6. The semiconductor processing system according to claim 5, wherein the first reactant and the second reactant are the same.

7. The semiconductor processing system according to claim 6, wherein the first reactant and the second reactant are different.

8. The semiconductor processing system according to claim 5, wherein at least one of the first reactant and the second reactant is selected from a nitrogen reactant, an oxygen reactant, a boron reactant, a carbon reactant, a phosphorous reactant, a sulfur reactant, a selenium reactant, and a tellurium reactant.

9. The semiconductor processing system according to claim 1, wherein at least one of the first sub cycle and the second sub cycle comprises a halidation pulse, wherein the halidation pulse comprises exposing the substrate to a halogen reactant.

10. The semiconductor processing system according to claim 1, wherein at least one of the first element and the second element is selected from a transition metal, a post transition metal, and a rare earth metal.

11. The semiconductor processing system according to claim 1, wherein the first element is a p-type dipole shifter and wherein the second element is an n-type dipole shifter.

12. The semiconductor processing system according to claim 1, wherein the first element and the second element are p-type dipole shifters.

13. The semiconductor processing system according to claim 12, wherein each p-type dipole shifter is selected from aluminum and nickel.

14. The semiconductor processing system according to claim 1, wherein the first element and the second element are n-type dipole shifters.

15. The semiconductor processing system according to claim 14, wherein each n-type dipole shifter is selected from yttrium and lanthanum.

16. The semiconductor processing system according to claim 1, wherein at least one of the first element and the second element are selected from a list consisting of La, Ni, Ga, Ta, Mg, Lu, Hf, La, Sc, Y, Al, Ba, Sr, Ti, V, and Gd.

17. The semiconductor processing system according to claim 1, wherein the cyclical deposition process further comprises one or more etching steps, ones from the one or more etching steps comprising exposing the substrate to an etchant.

18. The semiconductor processing system according to claim 1, wherein the cyclical deposition process further comprises one or more etching cycles, ones from the one or more etching cycles comprising a conversion reactant pulse and a volatilization reactant pulse, wherein the conversion reactant pulse comprises exposing the substrate to a conversion reactant, and wherein the volatilization reactant pulse comprises exposing the substrate to a volatilization reactant.

19. The semiconductor processing system according to claim 1 wherein at least one of the first precursor and the second precursor comprises vanadium bis-mesitylene.

20. A method of forming a dipole-forming layer, comprising:
providing a substrate to a reaction chamber; and
executing a cyclical deposition process comprising one or more super cycles, wherein ones from the one or more super cycles comprise sequentially executing a first sub cycle and a second sub cycle,
wherein the first sub cycle comprises a first precursor pulse that comprises exposing the substrate to a first precursor comprising a first element,
wherein the second sub cycle comprises a second precursor pulse that comprises exposing the substrate to a second precursor comprising a second element,
thereby forming the dipole-forming layer on the substrate, the dipole-forming layer comprising the first element and the second element.
